(19) United States
(12) Patent Application Publication
(10) Pub. No.: US 2022/0268848 A1
(43) Pub. Date: Aug. 25, 2022

(54) BATTERY MANAGEMENT SYSTEM

(71) Applicant: SAMSUNG SDI CO., LTD., Yongin-si (KR)

(72) Inventors: Sang Jin HONG, Yongin-si (KR); Sang Bong SIM, Yongin-si (KR)

(21) Appl. No.: 17/675,137

(22) Filed: Feb. 18, 2022

(30) Foreign Application Priority Data
Feb. 23, 2021 (KR) 10-2021-0023915

(51) Int. Cl. G01R 31/3835; H01M 10/42; H02J 7/00

(52) U.S. Cl. CPC G01R 31/3835; H01M 10/425; H02J 7/0014; H02J 7/0024; H01M 2010/4271

(57) ABSTRACT

A battery management system includes: a battery which includes battery cells connected in series; diodes which are connected in parallel to the battery cells; a switch unit which includes switches respectively connected to the battery cells; a control unit which detects voltages of the battery cells and performs cell balancing; and sensing lines which connect the battery cells and the control unit, wherein the control unit measures a first upper voltage difference between each battery cell and an adjacent upper battery cell in a state in which the switches are turned off, measures a second upper voltage difference between each battery cell and an adjacent upper battery cell after turning on the switches for a predetermined time, and, when the second upper voltage difference is greater than the first upper voltage difference, determines that the sensing line of the corresponding battery cell is disconnected.

### CROSS-REFERENCE TO RELATED APPLICATION

This application claims priority to and the benefit of Korean Patent Application No. 10-2021-0023915, filed on Feb. 23, 2021, in the Korean Intellectual Property Office, the entire contents of which are herein incorporated by reference.

### BACKGROUND

### 1. Field

Embodiments relate to a battery management system.

### 2. Description of the Related Art

Unlike a primary battery, which is not rechargeable, a secondary battery can be charged and discharged. Low-capacity secondary batteries may be used for, e.g., portable small-sized electronic devices, e.g., a smart phone, a feature phone, a notebook computer, a camcorder, and the like, and high-capacity secondary batteries may be used for, e.g., driving a motor for a hybrid car, an electric vehicle, a power storage cell, and the like.

The above information disclosed in this Background section is only for enhancement of understanding of the background of the described technology and therefore it may contain information that does not form the prior art that is already known in this country to a person of ordinary skill in the art.

### SUMMARY

An embodiment is directed to a battery management system, including: a battery which includes a plurality of battery cells connected in series; a plurality of diodes which are connected in parallel to the plurality of battery cells; a switch unit which includes a plurality of switches respectively connected to the plurality of battery cells; a control unit which detects voltages of the plurality of battery cells and performs cell balancing; and a plurality of sensing lines which connect the plurality of battery cells and the control unit, wherein the control unit measures a first upper voltage difference between each battery cell and an adjacent upper battery cell in a state in which the switches are turned off, measures a second upper voltage difference between each battery cell and an adjacent upper battery cell after turning on the switches for a predetermined time, and, when the second upper voltage difference is greater than the first upper voltage difference, determines that the sensing line of a corresponding battery cell is disconnected.

The control unit may measure a first lower voltage difference between each battery cell and an adjacent lower battery cell in a state in which the switches are turned off, may measure a second lower voltage difference between each battery cell and an adjacent lower battery cell after turning on the switches for a predetermined time, and, when the second lower voltage difference is greater than the first lower voltage difference, may determine that the sensing line of the corresponding battery cell is disconnected.

The disconnected sensing line may measure the voltage of the corresponding battery cell by dividing the voltage between the diode connected to the corresponding battery cell and the diode connected to the upper battery cell.

When the switches are turned on, the voltage of the adjacent upper battery cell of the disconnected sensing line may be increased.

When the switches are turned on, the voltage of the battery cell of the disconnected sensing line may be decreased.

In a state in which the switches are on, the voltage of the battery cell of the disconnected sensing line may correspond to the voltage of the adjacent lower battery cell.

In the switch unit, the switches of an even-numbered group and the switches of an odd-numbered group may be alternately turned on.

The control unit may turn on the switches of the even-numbered group to measure voltages of the even-numbered battery cells and then turn off the switches of the even-numbered group, and may turn on the switches of the odd-numbered group to measure voltages of the odd-numbered battery cells and then turn off the switches of the odd-numbered group.

### BRIEF DESCRIPTION OF DRAWINGS

Features will become apparent to those of skill in the art by describing in detail example embodiments with reference to the attached drawings in which:

FIG. 1 is a schematic diagram illustrating a battery management system according to an example embodiment.

FIGS. 2A and 2B are schematic diagrams for explaining a method for detecting the disconnection of a sensing line in a battery management system.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. In addition, it will be understood that when an element A is referred to as being “connected to” an element B, the element A can be directly connected to the element B or an intervening element C may be present therebetween such that the element A and the element B are indirectly connected to each other.

The terminology used herein is for the purpose of describing particular embodiments only and is not intended to be limiting of the disclosure. As used herein, the singular forms are intended to include the plural forms as well, unless the context clearly indicates otherwise. It will be further understood that the terms that the terms “comprise or include” and/or “comprising or including,” when used in this specification, specify the presence of stated features, numbers, steps, operations, elements, and/or components, but do not preclude the presence or addition of one or more other features, numbers, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

In addition, a control unit (controller) and/or other related devices or components according to the present disclosure may be implemented using any suitable hardware, firmware (e.g., application specific semiconductor), software, or a suitable combination of software, firmware, and hardware. For example, various components of the control unit and/or other related devices or parts according to the present disclosure may be formed on one integrated circuit chip or on separate integrated circuit chips. In addition, various components of the control unit may be implemented on a flexible printed circuit film, and may be formed on a tape carrier package, a printed circuit board, or the same substrate as the control unit.

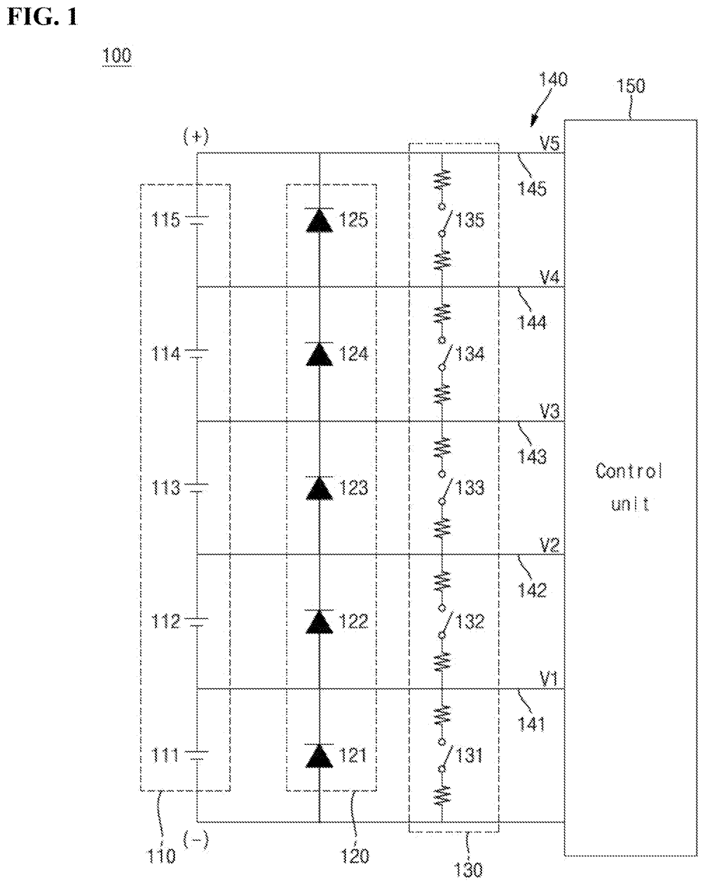

FIG. 1 is a schematic diagram illustrating a battery management system according to an example embodiment.

Referring to FIG. 1, a battery management system 100 according to an example embodiment includes a diode unit 120, a switch unit 130, a sensing unit 140, and a control unit 150. The battery management system 100 may be connected to a battery 110, to manage the battery 110.

The battery 110 may include a plurality of battery cells 111, 112, 113, 114, and 115, and may be charged or discharged at a constant voltage. In an example embodiment, the battery 110 may include a plurality of battery cells 111, 112, 113, 114, and 115 connected in series.

Although the battery 110 is illustrated in FIG. 1 as having five battery cells 111, 112, 113, 114, and 115 connected in series, the number of battery cells may be greater or less than five. For the sake of explanation, the battery 110 will be described as including a first battery cell 111, a second battery cell 112, a third battery cell 113, a fourth battery cell 114, and a fifth battery cell 115.

The first battery cell 111 may be a cell located at a minus terminal side of the battery 110, and the fifth battery cell 115 may be a cell located at a plus terminal side of the battery 110. The first battery cell 111 may be referred to as a lowermost battery cell, and the fifth battery cell 115 may be referred to as an uppermost battery cell.

The diode unit 120 may include a plurality of diodes 121, 122, 123, 124, and 125 connected in parallel to each of the plurality of battery cells 111, 112, 113, 114, 115. The number of diodes 121, 122, 123, 124, and 125 may correspond to the number of battery cells 111, 112, 113, 114 and 115. For example, the diode unit 120 may include a first diode 121, a second diode 122, a third diode 123, a fourth diode 124, and a fifth diode 125.

The plurality of diodes 121, 122, 123, 124, and 125 may allow the voltages of the battery cells 111, 112, 113, 114 and 115 to be measured even when at least one of sensing lines is disconnected. This will be described in additional detail below.

The switch unit 130 may include a plurality of switches 131, 132, 133, 134, and 135 connected to each of the plurality of battery cells 111, 112, 113, 114, and 115. For example, the switch unit 130 may include a first switch 131, a second switch 132, a third switch 133, a fourth switch 134, and a fifth switch 135.

The respective switches 131, 132, 133, 134, and 135 may open/close discharge paths of the corresponding battery cells 111, 112, 113, 114, and 115.

The sensing unit 140 may include a plurality of sensing lines 141, 142, 143, 144, and 145 for sensing voltages of each of the plurality of battery cells 111, 112, 113, 114, and 115. For example, the sensing unit 140 may include a first sensing line 141, a second sensing line 142, a third sensing line 143, a fourth sensing line 144, and a fifth sensing line 145.

The plurality of sensing lines 141, 142, 143, 144, and 145 may be connected to a plus side of each of the battery cells 111, 112, 113, 114 and 115.

The switch unit 130 may include a discharge resistor connected to both ends of each of the switches 131, 132, 133, 134, and 135, to perform cell balancing of the battery cells 111, 112, 113, 114, and 115. For example, a discharge resistor may be connected between each end of each of the switches 131, 132, 133, 134, and 135 and a corresponding one of the sensing lines 141, 142, 143, 144, and 145.

The control unit 150 may detect voltages, currents, temperatures, etc. of the respective battery cells 111, 112, 113, 114, and 115 which constitute the battery 110, and may control cell balancing for the battery 110. In an example embodiment, the control unit 150 may include a microprocessor, a central processing unit (CPU), and an application-specific integrated circuit (ASIC), such as an analog front end (AFE).

The control unit 150 may divide the switch unit 130 into an even-numbered group and an odd-numbered group. The even-numbered group may include the switches 132 and 134. The odd-numbered group may include the switches 131, 133, and 135. The control unit 150 may alternately turns on the switches 132 and 134 of the even-numbered group and the switches 131, 133, and 135 of the odd-numbered group to perform cell balancing. Accordingly, the control unit 150 may shorten the time required for cell balancing, compared to a case of sequentially balancing the plurality of battery cells 111, 112, 113, 114, and 115.

In addition, the control unit 150 may measure voltages before and after cell balancing of each of the battery cells 111, 112, 113, 114, and 115 to detect disconnection of the sensing lines 141, 142, 143, 144, and 145. This now will be described in additional detail.

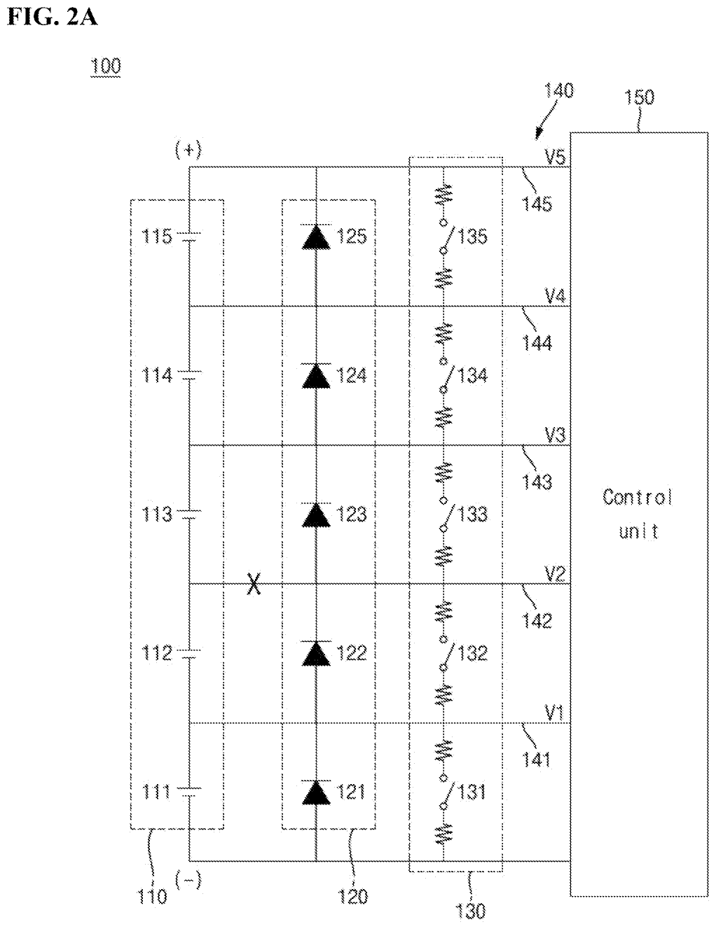

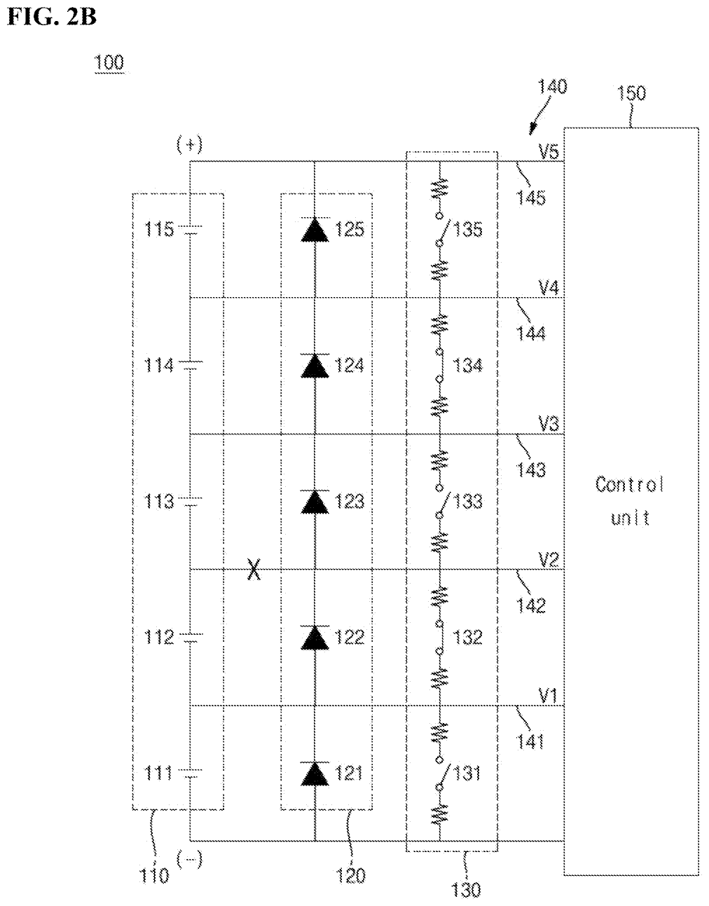

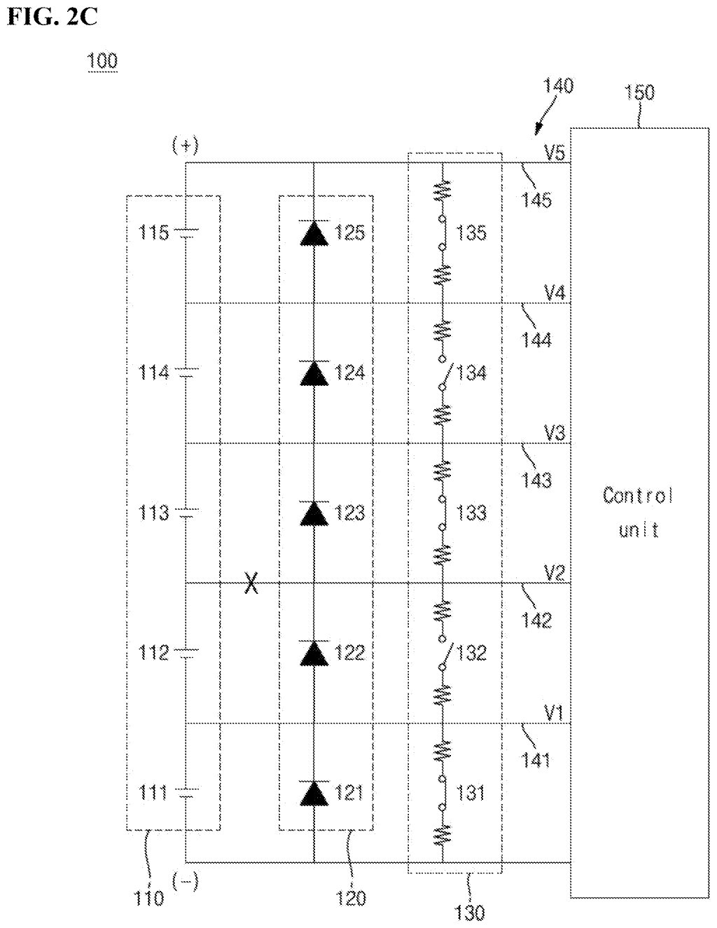

Hereinafter, a method in which the control unit 150 detects the disconnection of the sensing lines 141, 142, 143, 144, and 145 will be described in more detail. As an example, a case in which the second sensing line 142 (connected to the second battery cell 112) is disconnected (indicated by ‘X’ on the second sensing line 142 in FIGS. 2A-2C) will be described.

FIGS. 2A-2C are schematic diagrams for explaining a method for detecting the disconnection of a sensing line in a battery management system.

First, referring to FIG. 2A, the control unit 150 may measure voltages of the respective battery cells 111, 112, 113, 114, and 115 in a state in which the switch unit 130 is turned off, e.g., in which the switches 131, 132, 133, 134, and 135 are all open or nonconductive.

The control unit 150 may measure the voltages of the respective battery cells 111, 112, 113, 114, and 115 through the sensing unit 140. In an example embodiment, the control unit 150 may measure sensing voltages V1, V2, V3, V4, and V5 of the respective battery cells 111, 112, 113, 114, and 115 through the sensing lines 141, 142, 143, 144, and 145. The control unit 150 may obtain a difference between each of the sensing voltages V1, V2, V3, V4, and V5 of the respective battery cells 111, 112, 113, 114, and 115 and a sensing voltage of an adjacent lower battery cell to measure the voltages of the respective battery cells 111, 112, 113, 114, and 115.

Even when any one sensing line of the sensing unit 140 is disconnected (or opened), a sensing voltage may be measured from the disconnected sensing line by means of the diode unit 120. For example, referring to FIG. 2A, when the sensing voltage V3 measured from the third sensing line 143 is 9 V, and the sensing voltage V1 measured from the first sensing line 141 is 3 V, a sensing voltage V2 of 6 V, which is an intermediate voltage between the third diode 123 and the second diode 122, may be measured from the disconnected second sensing line 142 through the use of voltage division therebetween.

The control unit 150 may measure voltages of the respective battery cells 111, 112, 113, 114, and 115 by obtaining a difference between each of the sensing voltages measured from the respective sensing lines 141, 142, 143, 144, and 145 and the sensing voltage measured from an adjacent lower sensing line.

For example, the control unit 150 may obtain a difference (V3−V2) between 9 V (which is the sensing voltage V3 measured from the third sensing line 143) and 6 V (which is the sensing voltage V2 measured from the second sensing line 142), thereby determining that the voltage of the third battery cell 113 is 3 V.

Similarly, the control unit 150 may measure a difference (V2-V1) between 6 V (which is the sensing voltage V2 measured from the second sensing line 142) and 3 V (which is the sensing voltage V1 measured from the first sensing line 141), thereby determining that the voltage of the second battery cell 112 is 3 V.

In the same manner as described above, the control unit 150 may obtain the voltages of the respective battery cells 111, 112, 113, 114, and 115.

In addition, when the switch unit 130 is turned off, the control unit 150 may define a voltage difference between each of the battery cells 111, 112, 113, 114, and 115 and an adjacent upper battery cell as a first upper voltage difference and a voltage difference between each of the battery cells 111, 112, 113, 114, and 115 and an adjacent lower battery cell as a first lower voltage difference, to then store the same in a storage unit (not shown). Here, the first lower voltage difference means the voltage of each of the battery cells 111, 112, 113, 114, and 115.

Next, referring to FIG. 2B, the control unit 150 may turn on the switches 132 and 134 of the even-numbered group of the switch unit 130 to perform cell balancing for a predetermined period of time, and may then measure the sensing voltages of the even-numbered battery cells 112 and 114 to turn off the switches 132 and 134 of the even-numbered group.

Then, referring to FIG. 2C, the control unit 150 may turn on the switches 131, 133, and 135 of the odd-numbered group to perform cell balancing for a predetermined period of time, and may then measure the sensing voltages of the odd-numbered battery cells 111, 113, and 115 to turn off the switches 131, 133, and 135 of the odd-numbered group.

In an example embodiment, the cell balancing time may be set within several seconds.

When the sensing line is disconnected during cell balancing, the sensing voltage of the corresponding battery cell is measured similarly to the sensing voltage measured at the sensing line connected to the lower battery cell. Therefore, after cell balancing, the voltage difference between the sensing voltage of each battery cell and the sensing voltage of an adjacent lower battery cell becomes relatively lower than the voltage difference before cell balancing. In other words, in the battery cell connected to the disconnected sensing line, the voltage after cell balancing becomes lower than the voltage before cell balancing. In addition, since the voltage of the battery cell connected to the disconnected sensing line is lowered, the voltage of an adjacent upper battery cell is relatively increased. In addition, the control unit 150 may define, when the switch unit 130 is turned on, a voltage difference between each of the battery cells 111, 112, 113, 114, and 115 and an adjacent upper battery cell as a second upper voltage difference and a voltage difference between each of the battery cells 111, 112, 113, 114, and 115 and an adjacent lower battery cell as a second lower voltage difference to then store the same in the storage unit. Here, the second lower voltage difference means the voltage of each of the battery cells 111, 112, 113, 114, and 115 after cell balancing.

As such, when the second lower voltage difference between each of the battery cells 111, 112, 113, 114, and 115 and the adjacent lower battery cell is smaller than the first lower voltage difference, the control unit 150 may determine that the sensing line of the corresponding battery cell is disconnected. In addition, when the second upper voltage difference between each of the battery cells 111, 112, 113, 114, and 115 and the adjacent upper battery cell is smaller than the second upper voltage difference, the control unit 150 may determine that the sensing line of the corresponding battery cell is disconnected.

For example, referring again to FIG. 2B, when the second switch 132 is turned on, the second battery cell 112 is not connected to the second sensing line 142, and thus the voltage V2 is measured to be about 3 V, which is similar to the voltage V1 measured from the first sensing line 141. Accordingly, the control unit 150 may obtain a difference (V2−V1) between 3 V (which is the voltage V2 measured from the second sensing line 142) and 3 V (which is the voltage V1 measured from the first sensing line 141), thereby determining that the voltage of the second battery cell 112 is 0 V. In addition, the control unit 150 may obtain a difference (V3−V2) between 9 V (which is the voltage V3 measured from the third sensing line 143) and 3 V (which is the voltage V2 measured from the second sensing line 142), thereby determining that the voltage of the third battery cell 113 is 6 V.

Thus, the control unit 150 may compare the first upper voltage difference between each of the battery cells 111, 112, 113, 114, and 115 and the upper battery cell thereof before cell balancing, with the second upper voltage difference between each of the battery cells 111, 112, 113, 114, and 115 and the upper battery cell thereof after cell balancing, and, when the second upper voltage difference is greater than the first upper voltage difference, may determine that the sensing line of the corresponding battery cell is disconnected. In addition, the control unit 150 may compare the first lower voltage difference between each of the battery cells 111, 112, 113, 114, and 115 and the lower battery cell thereof before cell balancing, with the second lower voltage difference between each of the battery cells 111, 112, 113, 114, and 115 and the lower battery cell thereof after cell balancing, and, when the second lower voltage difference is greater than the first lower voltage difference, may determine that the sensing line of the corresponding battery cell is disconnected.

By way of summation and review, in a vehicle using a secondary battery, the performance of each cell may directly affect the performance of the vehicle. Thus, a charge/discharge of each cell may be managed by measuring a voltage and current of each cell. For this, a battery management system (BMS) capable of stably controlling the corresponding cell by monitoring a state of a sensing unit that senses each cell may be used.

As described above, embodiments may provide a battery management system capable of detecting disconnection of a sensing line of a battery cell. As described above, in a battery management system according to an example embodiment, a disconnection of a sensing line may be detected by comparing a voltage difference between each battery cell and an adjacent battery cell in a state in which switches are turned off with a voltage difference between each battery cell and an adjacent battery cell after turning on the switches, thereby improving safety.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A battery management system, comprising:
a plurality of diodes which are connected in parallel to a plurality of battery cells, the plurality of battery cells being connected in series;
a switch unit which includes a plurality of switches respectively connected to the plurality of battery cells;
a control unit which is configured to detect voltages of the plurality of battery cells and performs cell balancing; and
a plurality of sensing lines which connect the plurality of battery cells and the control unit,
wherein the control unit is further configured to:
measure a first upper voltage difference between each battery cell and an adjacent upper battery cell in a state in which the switches are turned off,
measure a second upper voltage difference between each battery cell and the adjacent upper battery cell after turning on the switches for a predetermined time, and
when the second upper voltage difference is greater than the first upper voltage difference, determine that a sensing line of a corresponding battery cell is a disconnected sensing line.

2. The battery management system as claimed in claim 1, wherein the control unit is configured to:
measure a first lower voltage difference between each battery cell and an adjacent lower battery cell in a state in which the switches are turned off,
measure a second lower voltage difference between each battery cell and the adjacent lower battery cell after turning on the switches for a predetermined time, and
when the second lower voltage difference is smaller than the first lower voltage difference, determine that the sensing line of the corresponding battery cell is disconnected.

3. The battery management system as claimed in claim 1, wherein the control unit is configured to use the disconnected sensing line to measure a voltage of the corresponding battery cell by dividing a voltage between a diode connected to the corresponding battery cell and a diode connected to the upper battery cell.

4. The battery management system as claimed in claim 1, wherein, when the switches are turned on, a voltage of the adjacent upper battery cell of the disconnected sensing line is increased.

5. The battery management system as claimed in claim 1, wherein, when the switches are turned on, a voltage of the battery cell of the disconnected sensing line is decreased.

6. The battery management system as claimed in claim 1, wherein, in a state in which the switches are on, a voltage of the battery cell of the disconnected sensing line corresponds to the voltage of an adjacent lower battery cell.

7. The battery management system as claimed in claim 1, wherein, in the switch unit, the switches of an even-numbered group and the switches of an odd-numbered group are alternately turned on.

8. The battery management system as claimed in claim 7, wherein the control unit is configured to turn on the switches of the even-numbered group to measure voltages of even-numbered battery cells and then turn off the switches of the even-numbered group, and turn on the switches of the odd-numbered group to measure voltages of odd-numbered battery cells and then turn off the switches of the odd-numbered group.
